(19) United States
(12) Patent Application Publication
(10) Pub. No.: US 2015/0114452 A1
(43) Pub. Date: Apr. 30, 2015

(54) Photovoltaic Modules and Methods for Making Same

(71) Applicant: ExxonMobil Chemical Patents Inc., Baytown, TX (US)

(72) Inventors: Scott C. Solis, Houston, TX (US); Danny Van Hoyweghen, Heverlee (BE); Ashley Kropf, Union Town, OH (US)

(21) Appl. No.: 14/391,096

(22) PCT Filed: May 7, 2013
(86) PCT No.: PCT/US2013/039906

§ 371 Date: Oct. 7, 2014

Related U.S. Application Data
(60) Provisional application No. 61/654,324, filed on Jun. 1, 2012.

(51) Int. Cl. H01L 31/048; H01L 31/0203

(52) U.S. Cl. CPC H01L 31/048; H01L 31/0203
USPC 136/251; 438/64

(57) ABSTRACT

This invention relates to photovoltaic modules wherein a polyethylene composition is used as an alternative, in whole or in part, to traditional ethylene vinyl acetate (EVA) resins in at least one layer. The polyethylene compositions are especially useful in the encapsulant and/or backsheet layers of photovoltaic modules. The polyethylene compositions comprise units derived from at least one C₄ to C₆ alpha-olefin comonomer, and have densities of 0.86 g/cm³ to 0.91 g/cm³.

### PRIORITY CLAIM

The present application claims priority to and the benefit of U.S. Ser. No. 61/654,324, filed Jun. 1, 2012, the disclosure of which is hereby incorporated by reference herein in its entirety.

### FIELD

This invention relates to photovoltaic modules and methods for making them, wherein a polyethylene composition is used as an alternative to traditional ethylene vinyl acetate (EVA) resins in at least one layer.

### BACKGROUND

A photovoltaic (PV) module is a packaged, linked assembly of photovoltaic cells. PV modules can include crystalline silicon wafers that are connected together and embedded in a laminating film. The laminating film and the embedded wafers are typically sandwiched between two layers (or panels) of glass, a polymeric material, or other suitable materials. PV modules can also include amorphous silicon, cadmium-telluride (CdTe) or copper-indium-diselenide (CuInSe₂, commonly referred to as “CIS”), or a similar semiconductor material deposited as a thin film on a substrate by well-known physical vapor deposition (“PVD”) or chemical vapor deposition (“CVD”) techniques. To complete the construction, the layers are etched and an adhesive is applied over the etching. A backing material is then applied over the adhesive.

Typically, two encapsulant layers are used, one below and one above the etching, to provide moisture, oxygen, and electrical isolation. The encapsulant layer that covers the face of the PV module is typically transparent. The other encapsulant layer, called the “backsheet,” is disposed on a “substrate” layer such as a tri-layer polyvinyl fluoride/polyethylene terephthalate/polyvinyl fluoride (PVF/PET/PVF) laminate sheet or other adequate polymer backsheet. Metal or polyimide films have also been used, adjacent to the backsheet, to provide further protection against outside influences, such as moisture. Additional details of PV modules and their construction methods can be found in, for example, U.S. Pat. Nos. 5,508,205; 6,066,796; and 6,420,646; 7,449,629; U.S. Patent Publication Nos. 2008-0245405; 2008-0276983; 2009-0101204; and 2009-0162666, as well as WO 2007-002618.

Encapsulant layers for PV modules are typically made from EVA resin. EVA resins are the most common material used in encapsulant layers today due to their favorable performance-to-cost ratio. EVA resins have a high rate of light transmission, can be formulated to adhere to glass and other polar substrates, and can be crosslinked to improve their thermal stability. The solar industry is rapidly growing, however, and the demand for EVA resins is increasing and supply is tightening. Hence, industry has sought possible alternatives to EVA resins for encapsulant layers in PV modules. This invention is directed to one such alternative.

### SUMMARY

This invention generally relates to PV modules and methods for making them, wherein a polyethylene composition is used as an alternative, in whole or in part, to traditional EVA resins in at least one layer. Where the polyethylene compositions described herein are used as an alternative in part to EVA, the layer may also comprise at least one low density polyethylene (“LDPE”) component. In an embodiment of the invention, this LDPE component is at least one compound selected from EVA, ethylene methyl acrylate, ethylene butyl acrylate, ethylene ethyl acrylate, ethylene acrylic acid or ethylene metacrylic acid copolymer or ionomer or terpolymer.

In one embodiment, this invention is directed to a PV module comprising a layer comprising a polyethylene composition, wherein the polyethylene composition comprises 50.0 to 99.5 wt % of polymer units derived from ethylene and 0.5 to 50.0 wt % of polymer units derived from at least one C₄ to C₆ alpha-olefin comonomer, based on the total weight of the polyethylene composition, and the polyethylene composition has a density of 0.86 to 0.91 g/cm³.

In another embodiment, this invention is directed to a method of making a PV module comprising providing a layer comprising a polyethylene composition, wherein the polyethylene composition comprises 50.0 to 99.5 wt % of polymer units derived from ethylene and 0.5 to 50.0 wt % of polymer units derived from at least one C₄ to C₆ alpha-olefin comonomer, based on the total weight of the polyethylene composition, and the polyethylene composition has a density of 0.86 to 0.91 g/cm³.

The polyethylene compositions are especially useful in the encapsulant layers or the backsheet layers of PV modules.

### DETAILED DESCRIPTION

This invention relates to photovoltaic modules and methods for making them, wherein a polyethylene composition is used as an alternative, in whole or in part, to traditional EVA resins in at least one layer. It has surprisingly been discovered that these compositions, like traditional EVA resins, have a high rate of light transmission, can be formulated to adhere to polar substrates, provide environmental protection and electrical isolation, and can be crosslinked to a high degree using peroxide or other known methods. Crosslinkability is desirable because crosslinking can improve a composition's final properties and decrease processing time for fabricating PV modules. Crosslinking of a resin in an encapsulant layer, for example, provides decreased cycle time, which increases productivity for the converters. Crosslinking also improves structural stability of the PV module and protection against mechanical or environmental impacts and chemical attack, providing longevity, wear resistance, and increased electrical isolation.

The polyethylene compositions can provide additional benefits over traditional EVA resins. They can provide better environmental protection for PV modules because they may have lower water vapor transmission rates (WVTR) than traditional EVA resins. Such compositions can also improve performance and life of PV modules because acetic acid, a possible decomposition product of traditional EVA resins, is not present or is present in lower amounts in PV modules comprising the inventive compositions. EVA, when exposed to water and/or ultraviolet radiation, can decompose to produce acetic acid. Acetic acid lowers the pH and increases the surface corrosion rates of the PV modules, and can thus lead to rapid PV module deterioration even when present in only small amounts. The reduction or elimination of acid as a decomposition product in PV modules has been a long-desired attribute in the market.

Applicants have surprisingly discovered that the polyethylene compositions provided for in this invention, when mixed with traditional EVA resins in an embodiment of the invention, can provide improved transparency in the final compositions versus EVA resins alone. Transparency of encapsulant layers of PV modules is an important property because it affects the efficiency of the modules. The useful life of a PV module may span a few decades, so even small or moderate decreases in efficiency can be significant and costly over that time period.

### Polyethylene Compositions

The polyethylene compositions generally comprise 50.0 to 99.5 wt % of polymer units derived from ethylene, and 0.5 to 50.0 wt % of polymer units derived from at least one C₄ to C₆ alpha-olefin comonomer, based on the total weight of the polyethylene composition. In an embodiment of the invention, the polyethylene compositions comprise about 87.0 mol % to about 97.5 mol % of polymer units derived from ethylene and about 13.0 mol % to about 2.5 mol % of polymer units derived from at least one C₄ to C₆ alpha-olefin comonomer. Suitable C₄ to C₆ alpha-olefins may be substituted or unsubstituted. Examples of suitable C₄ to C₆ alpha-olefins include 1-butene, cis-butene, trans-butene, 3,3,-dimethylbutene-1,4-methylpentene-1,1-hexene, etc.

Examples of suitable polyethylene compositions are the Exact™ plastomers (available from ExxonMobil Chemical Company).

The polyethylene compositions may be characterized by a density that is measured at 23° C. in accordance with ASTM D1505. The compositions have a density of about 0.86 g/cm³ to about 0.910 g/cm³, preferably about 0.88 to about 0.905 g/cm³, preferably about 0.870 g/cm³ to about 0.890 g/cm³, or more preferably about 0.86 g/cm³ to about 0.888 g/cm³.

In an embodiment of the invention, polyethylene compositions with densities from about 0.873 to about 0.888 g/cm³, about 0.875 to about 0.888 g/cm³, or from about 0.876 to about 0.888 g/cm³ are preferred. Many peroxides currently used in crosslinking processes in the industry have self-accelerating decomposition temperatures of between about 60° C. to about 80° C. It has been discovered that polyethylene compositions within these density ranges are likely to have a peak melting temperature within ±10° C. of the peak melting temperature of the many or most of the EVAs commercially used today. Thus, these compositions are useful to prevent premature reaction of the peroxide in the crosslinking process and more suited to be used as a replacement, in whole or in part, for the commercial EVAs used today. In one embodiment of the invention, the polyethylene composition has a peak melting temperature within ±10° C. of the peak melting temperature of at least one EVA commercially used today.

The polyethylene compositions have a CDBI>60, preferably >80, and more preferably >90. Fractions having an Mw below 15,000 are ignored when determining CDBI, as described in PCT Publication No. WO 93/03093, specifically columns 7 and 8, as well as in Wild et al., J. Poly. Sci., Poly. Phys. Ed., Vol. 20, p. 441 (1982) and U.S. Pat. No. 5,008,204.

The polyethylene compositions may also be characterized by a Differential Scanning calorimetry (“DSC”) melting point curve that exhibits a single melting point peak occurring in the region of 50° C. to 110° C. (second melt rundown). The polyethylene compositions can also be characterized by a peak melting temperature (also called “melting point”), Tm, measured by DSC. In an embodiment of the invention, the peak melting temperature is from about 10.0° C. to about 110.0° C., from about 20° C. to about 80° C., from about 20° C. to about 70° C., from about 20° C. to about 60° C., from about 30° C. to about 70° C., from about 30° C. to about 60° C., from about 40° C. to about 70° C., from about 40° C. to about 60° C., from about 30° C. to about 55° C., or from about 40° C. to about 55° C. The peak melting temperature can also be from any low value contemplated in these ranges to any high value.

In an embodiment of the invention, the polyethylene compositions also have a heat of fusion of greater than 75.0 J/g and preferably less than 130.0 J/g, 125.0 J/g, 120.0 J/g, 110.0 J/g, or 100.0 J/g, as measured by DSC.

The polyethylene compositions can also be characterized by a Vicat softening point, measured according to ASTM D1525. In an embodiment of the invention, the Vicat softening point is from about 20.0° C. to about 90.0° C., from about 20.0° C. to about 80.0° C., from about 20.0° C. to about 70.0° C., from about 30.0° C. to about 60.0° C., or from about 35.0° C. to about 45.0° C.; or can be from a low of about 20° C., to about 25.0° C., or about 30.0° C. to a high of about 35.0° C., to about 40.0° C., to about 50.0° C., to about 60.0° C., to about 70.0° C., or to about 80.0° C.

In an embodiment of the invention, the polyethylene compositions also have a Mw from about 70,000 to less than about 130,000 and a molecular weight distribution (Mw/Mn) equal to about 4.0 or less, and preferably from about 1.1 to about 3.5.

In an embodiment of the invention, the polyethylene compositions also have a 1% secant modulus, measured according to ASTM D790, of <about 1.5×10⁴ and as low as about 8×10² psi or even less.

The polyethylene compositions can also be characterized by a melt index (“MI”), measured according to ASTM D1238 using a 2.16 kg load at 190° C. MI refers to the viscosity of a polymer expressed as the weight of material which flows from a capillary of known dimensions under a specified load and temperature for a specified period of time. In an embodiment of the invention, the MI can be from about 0.1 to about 50.0 g/10 min, from about 0.1 to about 30.0, from about 0.5 to about 20.0 g/10 min, from about 0.5 to about 15.0 g/10 min, from about 0.5 to about 10.0 g/10 min, or from about 0.7 to about 5.0 g/10 min.

The polyethylene compositions can also be characterized by a crosslink index (MH-ML). MH-ML is the difference in torque of the molten resin before curing (ML) and after full curing (MH). The cure torque profile is measured over 15 minutes on an MDR 2000 Rheometer (manufactured by Alpha Technologies, a company with a business office in Akron, Ohio) at 150° C. A sample of the composition is combined with 1.5 phr of the peroxide OO-tert-butyl O-(2-ethylhexyl)monoperoxycarbonate in a preliminary low temperature (well above the melt temperature of the polymer, but also well below the initiation temperature of the peroxide, preferably below 100° C. or 90° C.) blending step using a blend mixer or other mixing equipment until a homogeneous blend is formed. The crosslink index (MH-ML) is a value of from about 1.0 dN*m to about 8.0 dN*m. In an embodiment of the invention, the crosslink index (MH-ML) is from a low of about 1.6 dN*m, 2.0 dN*m, 2.4 dN*m, 2.8 dN*m, 3.0 dN*m, 3.2 dN*m, 3.6 dN*m, or 5.0 dN*m, to a high of about 6.0 dN*m, about 6.5 dN*m, about 7.0 dN*m, about 7.5 dN*m, or about 8.0 dN*m.

In an embodiment of the invention, the polyethylene compositions further comprise one or more additives. Suitable additives include: stabilization agents such as antioxidants or other heat or light stabilizers, anti-static agents, crosslink agents or co-agents, crosslink promotors, release agents, adhesion promotors, plasticizers, or any other additive and derivatives known in the art. Suitable additives can further include one or more anti-agglomeration agents, such as oleamide, stearamide, erucamide, or other derivatives with the same activity, as would be known to one skilled in the art. Preferably, the compositions contains less than 0.15 wt % of such additives, based on the total weight of the composition. When present, the amount of the additives can also be from a low of about 0.01 wt %, about 0.02 wt %, about 0.03 wt %, or about 0.05 wt % to a high of about 0.06 wt %, about 0.08 wt %, about 0.11 wt %, or about 0.15 wt %, based on the total weight of the composition.

In an embodiment of the invention, the polyethylene compositions can also contain one or more antioxidants. Suitable antioxidants include phenolic antioxidants, such as butylated hydroxytoluene (BHT), or other derivatives containing butylated hydroxytoluene units, such as Irganox™ 1076, Irganox™ 1010 (available from BASF, a company with a business office in Florham Park, N.J.) and the like. The antioxidant can be present in an amount less than 0.05 wt %, based on the total weight of the composition. The amount can also be from a low of about 0.001 wt %, 0.005 wt %, 0.01 wt %, or 0.015 wt % to a high of about 0.02 wt %, 0.03 wt %, 0.04 wt %, or 0.05 wt %, based on the total weight of the composition.

The polyethylene compositions may be used as an alternative, in whole or in part, to traditional EVA in at least one layer of PV modules. In an embodiment of the invention, where the compositions are used as an alternative in whole to EVA, the layer does not comprise, or comprises less than 0.001 mole %, of any component selected from EVA, ethylene methyl acrylate, ethylene butyl acrylate, ethylene ethyl acrylate, ethylene acrylic acid or ethylene methacrylic acid copolymer or ionomer or terpolymer.

### LDPE Component

Where the polyethylene compositions described above are used as an alternative in part to traditional EVA, the layer may also comprise at least one LDPE component. In an embodiment of the invention, the amount of the LDPE component can be about 1.0 wt % to about 95.0 wt %, based on the total weight of the layer. In an embodiment of the invention, the amount of the at least one LDPE component can also be about 1.0 wt % to about 10.0 wt %, about 1.0 wt % to about 15.0 wt %, about 1.0 wt % to about 30.0 wt %, about 1.0 wt % to about 45.0 wt %, about 5.0 wt % to about 20.0 wt %, about 5.0 wt % to about 30.0 wt %, or about 5.0 wt % to about 45.0 wt %, based on the total weight of the layer. The amount of the at least one LDPE component can also be from a minimum of 1.0 wt %, 5.0 wt %, 10.0 wt %, 20.0 wt %, 30.0 wt %, 40.0 wt %, 50.0 wt %, or 60.0 wt % to a maximum of 20.0 wt %, 30.0 wt %, 40.0 wt %, 50.0 wt %, 60.0 wt %, 70.0 wt %, 80.0 wt %, 85.0 wt %, 90.0 wt %, 95.0 wt %, or 99.0 wt %.

In an embodiment of the invention, the LDPE component can have a density, measured according to ASTM D1505 at 23° C., of 0.9 g/cm³ to 1.2 g/cm³, or 0.92 g/cm³ to 1.0 g/cm³, or 0.94 g/cm³ to 0.98 g/cm³, or 0.92 g/cm³ to 0.96 g/cm³. The density can also range from a low of about 0.90 g/cm³, 0.92 g/cm³, or 0.94 g/cm³ to a high of about 0.98 g/cm³, 1.0 g/cm³, or 1.2 g/cm³.

In an embodiment of the invention, the LDPE component can have a melt index (“MI”) measured according to ASTM D1238 using a 2.16 kg load at 190° C., of less than about 500.0 g/10 min, less than about 400.0 g/10 min, less than about 300.0 g/10 min, less than about 200.0 g/10 min, less than about 100.0 g/10 min, less than about 50.0 g/10 min, or less than about 40.0 g/10 min. The MI can also be from a low of about 0.10 g/10 min, about 0.15 g/10 min, about 0.25 g/10 min, about 0.40 g/10 min, about 1.0 g/10 min, about 5.0 g/10 min, or about 10.0 g/10 min to a high of about 20 g/10 min, about 30 g/10 min, about 40 g/10 min, about 50 g/10 min, about 100 g/10 min, about 450 g/10 min, about 500 g/10 min, or about 550 g/10 min.

In an embodiment of the invention, the LDPE component can have a melting point, as measured by DSC, of about 40° C. or less. The melting point can be from about 40.0° C. to about 90.0° C., about 40.0° C. to about 80.0° C., about 50.0° C. to about 70.0° C., or about 55.0° C. to about 65.0° C. The melting point can also be from a low of about 40.0° C., about 45.0° C., or about 50.0° C. to a high of about 55.0° C., to about 65.0° C., or about 75.0° C. The melting point of the LDPE component can also be about 60.0° C.

In an embodiment of the invention, the LDPE component can have a Vicat softening point, as measured by ASTM D1525, of about 20.0° C. to about 80.0° C. The Vicat softening point can also be from a low of about 20.0° C., about 25.0° C., or about 30.0° C. to a high of about 35.0° C., about 40.0° C., or about 50.0° C. The Vicat softening point can also be about 20.0° C. to about 70.0° C., about 30.0° C. to about 60.0° C., about 35.0° C. to about 45.0° C., about 35.0° C., or about 40.0° C.

In an embodiment of the invention, the LDPE component has at least 5.0 wt % of polymer units derived from ethylene and 0.1 wt % to 10.0 wt % units derived from one or more modifiers, based on the total weight of the LDPE component. Typically, the amount of ethylene is about 50.0 wt % to about 99.0 wt %, about 55.0 wt % to about 95.0 wt %, about 60.0 wt % to about 90.0 wt %, or about 65.0 wt % to about 95.0 wt %. The amount of ethylene may also be from about 50.0 wt %, about 51.0 wt %, or about 55.0 wt % to about 80.0 wt %, about 90.0 wt %, or about 98.0 wt %.

In an embodiment of the invention, the LDPE component comprises one or more C₂ to C₁₂ modifiers. The C₂ to C₁₂ modifiers may be saturated or contain at least one unsaturation, but can also contain multiple conjugated or non-conjugated unsaturations. In case of multiple unsaturations, it is preferred that they are non-conjugated. In certain embodiments, the unsaturation of the C₂ to C₁₂ unsaturated modifier can be di-substituted with one or more alkyl groups in the beta position. Preferred C₂ to C₁₂ unsaturated modifiers include propylene, isobutylene, or combinations thereof.

Other suitable modifiers include, but are not limited to, tetramethylsilane, cyclopropane, sulfur hexafluoride, methane, t-butanol, perfluoropropane, deuterobenzene, ethane, ethylene oxide, 2,2-dimethylpropane, benzene, dimethyl sulfoxide, vinyl methyl ether, methanol, propane, 2-methyl-3-buten-2-ol, methyl acetate, t-butyl acetate, methyl formate, ethyl acetate, butane, triphenylphosphine, methylamine, methyl benzoate, ethyl benzoate, N,N-diisopropylacetamide, 2,2,4-trimethylpentane, n-hexane, isobutane, dimethoxymethane, ethanol, n-heptane, n-butyl acetate, cyclohexane, methylcyclohexane, 1,2-dichlorethane, acetonitrile, N-ethylacetamide, propylene, 1-butene, n-decane, N,N-diethylacetamide, cyclopentane, acetic anhydride, n-tridecane, n-butyl benzoate, isopropanol, toluene, hydrogen, acetone, 4,4-dimethylpentene-1, trimethylamine, N,N-dimethylacetamide, isobutylene, n-butyl isocyanate, methyl butyrate, n-butylamine, N,N-dimethylformamide, diethyl sulfide, diisobutylene, tetrahydrofuran, 4-methylpentene-1, p-xylene, p-dioxane, trimethylamine, butene-2, 1-bromo-2-chlorethane, octene-1, 2-methylbutene-2, cumene, butene-1, methyl vinyl sulfide, n-butyronitrile, 2-methylbutene-1, ethylbenzene, n-hexadecene, 2-butanone, n-butyl isothiocyanate, methyl 3-cyanopropionate, tri-n-butylamine, 3-methyl-2-butanone, isobutyronitrile, di-n-butylamine, methyl chloroacetate, 3-methylbutene-1,1,2-dibromoethane, dimethylamine, benzaldehyde, chloroform, 2-ethylhexene-1, propionaldehyde, 1,4 dichlorobutene-2, tri-n-butylphosphine, dimethylphosphine, methyl cyanoacetate, carbon tetrachloride, bromotrichloromethane, di-n-butylphosphine, acetaldehyde, propionaldehyde, and phosphine. Further details and other suitable modifiers are described in Advances in Polymer Science, Vol. 7, pp. 386-448 (1970).

The amount of the modifier(s) can range from a low of about 0.1 wt %, about 0.2 wt %, about 0.3 wt %, about 0.4 wt %, or about 0.8 wt % to a high of about 1.5 wt %, about 2.5 wt %, about 3.0 wt %, about 3.6 wt %, about 5.0 wt %, about 6.0 wt %, or about 10.0 wt %, based on the total weight of the LDPE component. The amount of the modifier can also be about 0.1 wt % to about 8.0 wt %, about 0.2 wt % to about 6.0 wt %, about 0.3 wt % to about 6.0 wt %, about 0.3 wt % to about 4.0 wt %, about 0.4 wt % to about 4.0 wt %, about 0.6 wt % to about 4.0 wt %, about 0.4 wt % to about 3.5 wt %, or about 0.5 wt % to about 3.8 wt %, based on the total weight of the LDPE component.

In an embodiment of the invention, the LDPE component comprises polymer units derived from one or more polar comonomers. The amount of polymer units derived from polar comonomers can be up to 95.0 wt % and can also be from about 1.0 wt % to about 5.0 wt %, about 1.0 wt % to about 49.0 wt %, about 5.0 wt % to about 45.0 wt %, about 10.0 wt % to about 50.0 wt %, about 10.0 wt % to about 40.0 wt %, or about 30.0 wt % to about 45.0 wt %, based on the total weight of the LDPE component. The amount of polymer units derived from polar comonomers can also be from a low of about 1.0 wt %, about 4.0 wt %, or about 7.0 wt % to a high of about 30.0 wt %, about 40.0 wt %, or about 45.0 wt %.

Suitable polar comonomers include, for example, vinyl ethers such as vinyl methyl ether, vinyl n-butyl ether, vinyl phenyl ether, vinyl beta-hydroxy-ethyl ether, and vinyl dimethylamino-ethyl ether; olefins such as propylene, butene-1, cis-butene-2, trans-butene-2, isobutylene, 3,3,-dimethylbutene-1, 4-methylpentene-1, octene-1, and styrene; vinyl type-esters such as vinyl acetate, vinyl butyrate, vinyl pivalate, and vinylene carbonate; haloolefins such as vinyl fluoride, vinylidene fluoride, tetrafluoroethylene, vinyl chloride, vinylidene chloride, tetrachloroethylene, and chlorotrifluoroethylene; acrylic-type esters such as methyl acrylate, ethyl acrylate, n-butyl acrylate, t-butyl acrylate, 2-ethylhexyl acrylate, alpha-cyanoisopropyl acrylate, beta-cyanoethyl acrylate, o-(3-phenylpropan-1,3,-dionyl)phenyl acrylate, methyl methacrylate, n-butyl methacrylate, t-butyl methacrylate, cyclohexyl methacrylate, 2-ethylhexyl methacrylate, methyl methacrylate, glycidyl methacrylate, beta-hydroxethyl methacrylate, beta-hydroxpropyl methacrylate, 3-hydroxy-4-carbo-methoxy-phenyl methacrylate, N,N-dimethylaminoethyl methacrylate, t-butylaminoethyl methacrylate, 2-(1-aziridinyl)ethyl methacrylate, diethyl fumarate, diethyl maleate, and methyl crotonate; other acrylic-type derivatives such as acrylic acid, methacrylic acid, crotonic acid, maleic acid, methyl hydroxy, maleate, itaconic acid, acrylonitrile, fumaronitrile, N,N-dimethylacrylamide, N-isopropylacrylamide, N-t-butylacrylamide, N-phenylacrylamide, diacetone acrylamide, methacrylamide, N-phenylmethacrylamide, N-ethylmaleimide, and maleic anhydride; and other compounds such as allyl alcohol, vinyltrimethylsilane, vinyltriethoxysilane, N-vinylcarbazole, N-vinyl-N-methylacetamide, vinyldibutylphosphine oxide, vinyldiphenylphosphine oxide, bis-(2-chloroethyl) vinylphosphonate and vinyl methyl sulfide.

In an embodiment of the invention, the polar comonomer is vinyl acetate (VA). The resulting EVA resin can have about 5.0 wt % to about 95.0 wt %, typically about 20.0 wt % to about 80.0 wt %, of polymer units derived from VA, based on total weight of the EVA resin. The amount of polymer units derived from VA can also be from a low of about 20.0 wt %, about 25.0 wt %, about 30.0 wt %, about 35.0 wt %, or about 40.0 wt % to a high of about 45.0 wt %, about 50.0 wt %, about 55.0 wt %, about 60.0 wt %, or about 80.0 wt %, based on the total weight of the EVA resin. In certain embodiments, the EVA resin can further include polymer units derived from one or more comonomers selected from propylene, butene, 1-hexene, 1-octene, and/or one or more dienes. Suitable dienes include, for example, 1,4-hexadiene, 1,6-octadiene, 5-methyl-1,4-hexadiene, 3,7-dimethyl-1,6-octadiene, dicyclopentadiene (DCPD), ethylidene norbornene (ENB), norbornadiene, 5-vinyl-2-norbornene (VNB), and combinations thereof.

In an embodiment of the invention, the LDPE component is at least one compound selected from EVA, ethylene methyl acrylate, ethylene butyl acrylate, ethylene ethyl acrylate, ethylene acrylic acid or ethylene metacrylic acid copolymer or ionomer or terpolymer.

In an embodiment of the invention, the LDPE component can also contain one or more antioxidants. Phenolic antioxidants are preferred, such as butylated hydroxytoluene (BHT) or other derivatives containing butylated hydroxytoluene units such as Irganox™ 1076 or Irganox™ 1010 (available from BASF, a company with a business office in Florham Park, N.J.) and the like. The antioxidant can be present in an amount less than 0.05 wt %, based on the total weight of the LDPE component. The amount can be from a low of about 0.001 wt %, about 0.005 wt %, about 0.01 wt %, or about 0.015 wt % to a high of about 0.02 wt %, about 0.03 wt %, about 0.04 wt %, or about 0.05 wt %, based on the total weight of the LDPE component.

In an embodiment of the invention, the LDPE component can further contain one or more additives. Suitable additives can include, for example, stabilization agents such as antioxidants or other heat or light stabilizers; anti-static agents; crosslink agents or co-agents; crosslink promotors; release agents; adhesion promotors; plasticizers; or any other additive and derivatives known in the art. Suitable additives can further include one or more anti-agglomeration agents, such as oleamide, stearamide, erucamide or other derivatives with the same activity, as known to a person of ordinary skill in the art. Preferably, the LDPE component contains less than about 0.15 wt % of such additives, based on the total weight of the LDPE component. When present, the amount of the additive(s) can range from a low of about 0.01 wt %, about 0.02 wt %, about 0.03 wt %, or about 0.05 wt % to a high of about 0.06 wt %, about 0.08 wt %, about 0.11 wt %, or about 0.15 wt %, based on the total weight of the LDPE component.

### Blends

The polyethylene compositions, including those where an LDPE component is present, may be useful in blends with other polyolefins or compounds, in addition to those discussed above. Synergistic blends that improve light transmittance, crosslinkability, or barrier properties may be formed.

In an embodiment of the invention, the polyethylene composition further comprises polyisobutylene and is especially useful in the backsheet layers of PV modules.

The polyethylene compositions, LDPE components, and other materials disclosed herein can be produced in any suitable process, and such processes are well known in the art.

### EXAMPLES

The following examples are provided to demonstrate particular embodiments of the invention. One of ordinary skill in the art will readily appreciate that additional embodiments are possible without departing from the scope and spirit of the invention.

### Crosslinking

The following procedure was followed for Samples 1-5 and Comparative Samples 1-5. The resins used in each sample included various grades of Exact™, ethylene-based alpha-olefin copolymer resins commercially available from ExxonMobil Chemical Company, except Comparative Sample 1, which used a high pressure EVA resin (hereinafter “HEVA”). A sample of each resin was combined at 80° C. on a roll mill (available from Agila Machinery, a company with a business office in Belgium) with 1.5 phr of the peroxide OO-tert-butyl O-(2-ethylhexyl)monoperoxycarbonate until a homogeneous blend was formed. A cure torque profile was then measured for each sample on an MDR 2000 Rheometer to determine the crosslink index (MH-ML). Properties of each resin prior to crosslinking and the results of the crosslinking process are summarized in Table 1 below.

TABLE 1
Properties and Crosslink Index of Samples 1-5 and Comparative Samples 1-5

| | | Copolymer | MI | Density | Tm | (MH-ML) |
|---|---|---|---|---|---|---|
| Sample | Resin | Type | (g/10 min)⁺ | (g/cm³)⁺ | (° C.)⁺ | (dN * m) |
| 1 | Exact ™ 4049 | C₂-C₄ | 4.5 | 0.873 | 53 | 5.86 |
| 2 | Exact ™ 9361 | C₂-C₄ | 3.5 | 0.864 | 41 | 5.47 |
| 3 | Exact ™ 9371 | C₂-C₄ | 4.5 | 0.872 | 55 | 6.09 |
| 4 | Exact ™ 3040 | C₂-C₆ | 17 | 0.900 | 95 | 3.36 |
| 5 | Exact ™ 3139 | C₂-C₆ | 7.5 | 0.900 | 95 | 5.01 |
| Comp 1 | UL04331EL | HEVA | 43 | 0.954 | 66 | 4.23 |
| Comp 2 | Exact ™ 8210 | C₂-C₈ | 10 | 0.882 | 73 | 3.81 |
| Comp 3 | Exact ™ 8230 | C₂-C₈ | 30 | 0.882 | 73 | 2.12 |
| Comp 4 | Exact ™ 0210 | C₂-C₈ | 10 | 0.902 | 95 | 2.98 |
| Comp 5 | Exact ™ 0230 | C₂-C₈ | 30 | 0.902 | 97 | 1.64 |

⁺Before crosslinking.

### Transparency and Haze

The following procedure was followed to measure transparency for Samples 1-5 and Comparative Samples 1-5 above, both before and after the crosslinking procedure above was completed. UV and visible transparency were measured using a Shimadzu UV-VIS spectrophotometer UV-2100 (available from Shimadzu Corporation, a company with a business office in Japan). UV transparency was measured at a wavelength of between 190 and 380 nm and visible transparency was measure at between 380 and 780 nm. Haze was measured according to ASTM D1003 using a Hunterlab Ultrascan SE spectrophotometer (available from Hunter Associates Laboratory, Inc., a company with a business office in Reston, Va.). The results are summarized in Table 2.

TABLE 2
Transparency of Samples 1-9 and Comparative Samples 1 and 2

| | Sample | | | | | | | | | |
|---|---|---|---|---|---|---|---|---|---|---|
| | 1 | 2 | 3 | 4 | 5 | Comp 1 | Comp 2 | Comp 3 | Comp 4 | Comp 5 |
| MI/ | 4.5/ | 3.5/ | 4.5/ | 17/ | 7.5/ | 43/ | 10/ | 30/ | 10/ | 30/ |
| Density | 0.873 | 0.864 | 0.872 | 0.900 | 0.900 | 0.954 | 0.882 | 0.882 | 0.902 | 0.902 |

Non-cured

| | | | | | | | | | | |
|---|---|---|---|---|---|---|---|---|---|---|
| 190 to | 60.0 | 61.9 | 60.8 | 69.1 | 40.1 | 61.6 | 59.6 | 64.2 | 58.2 | 68.7 |
| 380 nm | | | | | | | | | | |
| (UV) | | | | | | | | | | |
| 380 to | 91.7 | 91.8 | 91.7 | 90.4 | 61.9 | 92.2 | 91.7 | 91.4 | 90.9 | 91.3 |
| 780 nm | | | | | | | | | | |
| (VIS) | | | | | | | | | | |

Cured

| | | | | | | | | | | |
|---|---|---|---|---|---|---|---|---|---|---|
| 190 to | 58.8 | 57.5 | 58.9 | 56.4 | 36.5 | 54.5 | 53.0 | 61.5 | 45.8 | 60.5 |
| 380 nm | | | | | | | | | | |
| (UV) | | | | | | | | | | |
| 380 to | 91.7 | 91.2 | 91.7 | 90.5 | 67.1 | 92.4 | 91.6 | 91.2 | 88.9 | 90.9 |
| 780 nm | | | | | | | | | | |
| (VIS) | | | | | | | | | | |
| Internal | 2.6 | 2.2 | 3.0 | 3.6 | 3.3 | 0.1 | 2.1 | 2.2 | 3.8 | 2.7 |
| Haze | | | | | | | | | | |
| Surface | 3.5 | 3.9 | 5.3 | 4.7 | 3.7 | 3.0 | 3.4 | 4.5 | 7.6 | 3.5 |
| Haze | | | | | | | | | | |
| Total | 6.1 | 6.2 | 8.3 | 8.3 | 7.0 | 3.1 | 5.5 | 6.7 | 11.4 | 6.2 |
| Haze | | | | | | | | | | |

### Particular Embodiments

Exemplary, but non-limiting embodiments of the invention, are described below.

### Embodiment A

A photovoltaic module comprising a layer comprising a polyethylene composition, wherein said polyethylene composition comprises:
a. 50.0 wt % to 99.5 wt % of polymer units derived from ethylene, and
b. 0.5 wt % to 50.0 wt % of polymer units derived from at least one C₄ to C₆ alpha-olefin comonomer,
   based on the total weight of said polyethylene composition, and said polyethylene composition has a density, according to ASTM D1505 at 23° C., of 0.86 g/cm³ to 0.91 g/cm³.

### Embodiment B

A photovoltaic module comprising a layer comprising a polyethylene composition, wherein said polyethylene composition comprises:
a. 87.0 mol % to 97.5 mol % of polymer units derived from ethylene, and
b. 13.0 mol % to 2.5 mol % of polymer units derived from at least one C₄ to C₆ alpha-olefin comonomer,
   based on the total moles of said polyethylene composition, and said polyethylene composition has a density, according to ASTM D1505 at 23° C., of 0.86 g/cm³ to 0.91 g/cm³.

### Embodiment C

The photovoltaic module of Embodiment A or B wherein said layer further comprises at least one component selected from ethylene vinyl acetate, ethylene methyl acrylate, ethylene butyl acrylate, ethylene ethyl acrylate, ethylene acrylic acid or ethylene metacrylic acid copolymer or ionomer or terpolymer.

### Embodiment D

The photovoltaic module of Embodiment C wherein the amount of said at least one component is from 5 wt % to 95 wt %, based on the total weight of said layer.

### Embodiment E

The photovoltaic module of Embodiment A or B wherein said layer comprises less than 0.001 mole % of any component selected from ethylene vinyl acetate, ethylene methyl acrylate, ethylene butyl acrylate, ethylene ethyl acrylate, ethylene acrylic acid or ethylene metacrylic acid copolymer or ionomer or terpolymer.

### Embodiment F

The photovoltaic module of Embodiment A or B wherein said polyethylene composition has a melt index, according to ASTM D1238 at 190° C./2.16 kg, of about 0.1 g/10 min to about 500.0 g/10 min.

### Embodiment G

The photovoltaic module of Embodiment A or B wherein said polyethylene composition has a melt index, according to ASTM D1238 at 190° C./2.16 kg, of about 0.1 g/10 min to about 200.0 g/10 min.

### Embodiment H

The photovoltaic module of Embodiment A or B wherein said polyethylene composition has a melt index, according to ASTM D1238 at 190° C./2.16 kg, of about 0.1 g/10 min to about 40.0 g/10 min.

### Embodiment I

The photovoltaic module of Embodiment A or B wherein said polyethylene composition has a melt index, according to ASTM D1238 at 190° C./2.16 kg, of about 0.9 g/10 min to about 4.5 g/10 min.

### Embodiment J

The photovoltaic module of Embodiment A wherein said polyethylene composition comprises:
a. 50.0 wt % to 95.5 wt % of polymer units derived from ethylene, and
b. 1.0 wt % to 35.0 wt % of polymer units derived from at least one C₄ to C₆ alpha-olefin comonomer,
   based on the total weight of said polyethylene composition, and said polyethylene composition has a composition distribution breadth index above 90%, a density according to ASTM D1505 at 23° C. of 0.873 g/cm³ to 0.888 g/cm³, and a melt index according to ASTM D1238 at 190° C./2.16 kg of 0.5 g/10 min to 5 g/10 min.

### Embodiment K

The photovoltaic module of Embodiment B wherein said polyethylene composition comprises:
a. 87.0 mol % to 97.5 mol % of polymer units derived from ethylene, and
b. 13.0 mol % to 2.5 mol % of polymer units derived from at least one C₄ to C₆ alpha-olefin comonomer,
   based on the total moles of said polyethylene composition, and said polyethylene composition has a composition distribution breadth index above 90%, a density according to ASTM D1505 at 23° C. of 0.873 g/cm³ to 0.888 g/cm³, and a melt index according to ASTM D1238 at 190° C./2.16 kg of 0.5 g/10 min to 5 g/10 min.

### Embodiment L

The photovoltaic module of Embodiments A-K wherein said polyethylene composition has a density, according to ASTM D1505 at 23° C., of about 0.86 g/cm³ to about 0.888 g/cm³.

### Embodiment M

The photovoltaic module of Embodiments A-K wherein said polyethylene composition has a density, according to ASTM D1505 at 23° C., of about 0.873 g/cm³ to about 0.888 g/cm³.

### Embodiment N

The photovoltaic module of Embodiments A-M wherein said polyethylene composition has a peak melting temperature of about 10° C. to about 110° C.

### Embodiment O

The photovoltaic module of Embodiments A-N wherein the polyethylene composition has a crosslink index (MH-ML) of about 1.6 dN*m or greater, preferably about 3.0 dN*m or greater, preferably between about 3.6 dN*m and about 8.0 dN*m, and more preferably between about 5.0 dN*m and about 8.0 dN*m.

### Embodiment P

The photovoltaic module of Embodiments A-O wherein said polyethylene composition comprises one or more C₃ to C₁₂ modifiers.

### Embodiment Q

The photovoltaic module of Embodiments A-P wherein said polyethylene composition has a peak melting temperature within ±10° C. of the peak melting temperature of at least one commercial EVA.

### Embodiment R

The photovoltaic module of Embodiments A-Q wherein said layer is a backsheet layer and said backsheet layer further comprises polyisobutylene.

### Embodiment S

A method of making a photovoltaic cell comprising providing a layer comprising a polyethylene composition, wherein said polyethylene composition comprises:
a. 50.0 wt % to 99.5 wt % of polymer units derived from ethylene, and
b. 0.5 wt % to 50.0 wt % of polymer units derived from at least one C₄ to C₆ alpha-olefin comonomer,
   based on the total weight of said polyethylene composition, and said polyethylene composition has a density, according to ASTM D1505 at 23° C., of 0.86 g/cm³ to 0.91 g/cm³.

### Embodiment T

A method of making a photovoltaic cell comprising providing a layer comprising a polyethylene composition, wherein said polyethylene composition comprises:
a. 87.0 mol % to 97.5 mol % of polymer units derived from ethylene, and
b. 13.0 mol % to 2.5 mol % of polymer units derived from at least one C₄ to C₆ alpha-olefin comonomer,
   based on the total moles of said polyethylene composition, and said polyethylene composition has a density, according to ASTM D1505 at 23° C., of 0.86 g/cm³ to 0.91 g/cm³.

### Embodiment U

The method of Embodiment S or T wherein said layer further comprises at least one component selected from ethylene vinyl acetate, ethylene methyl acrylate, ethylene butyl acrylate, ethylene ethyl acrylate, ethylene acrylic acid or ethylene metacrylic acid copolymer or ionomer or terpolymer.

### Embodiment V

The method of Embodiment S or T wherein said encapsulant layer comprises less than 0.001 mole % of any component selected from ethylene vinyl acetate, ethylene methyl acrylate, ethylene butyl acrylate, ethylene ethyl acrylate, ethylene acrylic acid or ethylene metacrylic acid copolymer or ionomer or terpolymer.

### Embodiment W

The method of Embodiments S-V wherein said polyethylene composition has a melt index, according to ASTM D1238 at 190° C./2.16 kg, of about 0.1 g/10 min to about 500.0 g/10 min.

### Embodiment X

The method of Embodiments S-V wherein said polyethylene composition has a melt index, according to ASTM D1238 at 190° C./2.16 kg, of about 0.1 g/10 min to about 200.0 g/10 min.

### Embodiment Y

The method of Embodiments S-V wherein said polyethylene composition has a melt index, according to ASTM D1238 at 190° C./2.16 kg, of about 0.1 g/10 min to about 40.0 g/10 min.

### Embodiment Z

The method of Embodiments S-V wherein said polyethylene composition has a melt index, according to ASTM D1238 at 190° C./2.16 kg, of about 0.9 g/10 min to about 4.5 g/10 min.

### Embodiment AA

The method of Embodiment S wherein said polyethylene composition comprises:
a. at least 50.0 wt % of polymer units derived from ethylene, and
b. 1.0 wt % to 35.0 wt % of polymer units derived from at least one C₄ to C₆ alpha-olefin,
   based on the total weight of said polyethylene composition, and said polyethylene composition has a composition distribution breadth index above 90%, a density according to ASTM D1505 at 23° C. of 0.873 g/cm³ to 0.888 g/cm³, and a melt index according to ASTM D1238 at 190° C./2.16 kg of 0.5 g/10 min to 5 g/10 min.

### Embodiment AB

The method of Embodiment T wherein said polyethylene composition comprises:
a. 87.0 mol % to 97.5 mol % of polymer units derived from ethylene, and
b. 13.0 mol % to 2.5 mol % of polymer units derived from at least one C₄ to C₆ alpha-olefin comonomer,
   based on the total moles of said polyethylene composition, and said polyethylene composition has a composition distribution breadth index above 90%, a density according to ASTM D1505 at 23° C. of 0.873 g/cm³ to 0.888 g/cm³, and a melt index according to ASTM D1238 at 190° C./2.16 kg of 0.5 g/10 min to 5 g/10 min.

### Embodiment AC

The method of Embodiments S-Z wherein said polyethylene composition has a density, according to ASTM D1505 at 23° C., of about 0.86 g/cm³ to about 0.888 g/cm³.

### Embodiment AD

The method of Embodiments S-Z wherein said polyethylene composition has a density, according to ASTM D1505 at 23° C., of about 0.873 g/cm³ to about 0.888 g/cm³.

### Embodiment AE

The method of Embodiments S-AD wherein said polyethylene composition has a crosslink index (MH-ML) of about 1.6 dN*m or greater, preferably about 3.0 dN*m or greater, preferably between about 3.6 dN*m and about 8.0 dN*m, and more preferably between about 5.0 dN*m and about 8.0 dN*m.

### Embodiment AF

The method of Embodiments S-AE wherein said polyethylene composition comprises one or more C₃ to C₁₂ modifiers.

### Embodiment AG

The method of Embodiments S-AF wherein said layer is a backsheet layer and said backsheet layer further comprises polyisobutylene.

### Embodiment AH

The method of Embodiments S-AG wherein said polyethylene composition has a peak melting temperature within ±10° C. of the peak melting temperature of at least one commercial EVA.

1. A photovoltaic module having a layer comprising a polyethylene composition, wherein said polyethylene composition comprises:
a. 50.0 wt % to 99.5 wt % of polymer units derived from ethylene, and
b. 0.5 wt % to 50.0 wt % of polymer units derived from at least one C₄ to C₆ alpha-olefin comonomer,
based on the total weight of said polyethylene composition, and said polyethylene composition has a density, in accordance with ASTM D1505 at 23° C., of 0.86 g/cm³ to 0.91 g/cm³.

2. The photovoltaic module of claim 1 wherein said layer further comprises at least one component selected from ethylene vinyl acetate, ethylene methyl acrylate, ethylene butyl acrylate, ethylene ethyl acrylate, ethylene acrylic acid and ethylene metacrylic acid copolymer or ionomer or terpolymer.

3. The photovoltaic module of claim 1 wherein the amount of said at least one component is from 5 wt % to 95 wt %, based on the total weight of said layer.

4. The photovoltaic module of claim 1 wherein said layer comprises less than 0.001 mole % of any of ethylene vinyl acetate, ethylene methyl acrylate, ethylene butyl acrylate, ethylene ethyl acrylate, ethylene acrylic acid and ethylene metacrylic acid copolymer or ionomer or terpolymer.

5. The photovoltaic module of claim 1 wherein said polyethylene composition has a melt index, according to ASTM D1238 at 190° C./2.16 kg, of about 0.1 g/10 min to about 200.0 g/10 min.

6. The photovoltaic module of claim 1 wherein said polyethylene composition has a melt index, according to ASTM D1238 at 190° C./2.16 kg, of about 0.1 g/10 min to about 40.0 g/10 min.

7. The photovoltaic module of claim 1 wherein said polyethylene composition has a melt index, according to ASTM D1238 at 190° C./2.16 kg, of about 0.9 g/10 min to about 4.5 g/10 min.

8. The photovoltaic module of claim 1 wherein said polyethylene composition comprises:
a. 50.0 wt % to 95.5 wt % of polymer units derived from ethylene, and
b. 1.0 wt % to 35.0 wt % of polymer units derived from at least one C₄ to C₆ alpha-olefin comonomer,
based on the total weight of said polyethylene composition, and said polyethylene composition has a composition distribution breadth index above 90%, a density according to ASTM D1505 at 23° C. of 0.873 g/cm³ to 0.888 g/cm³, and a melt index according to ASTM D1238 at 190° C./2.16 kg of 0.5 g/10 min to 5 g/10 min.

9. The photovoltaic module of claim 1 wherein said polyethylene composition has a density, according to ASTM D1505 at 23° C., of about 0.873 g/cm³ to about 0.888 g/cm³.

10. The photovoltaic module of claim 1 wherein said polyethylene composition has a peak melting temperature of about 10° C. to about 110° C.

11. The photovoltaic module of claim 1 wherein the polyethylene composition has a crosslink index (MH-ML) of about 1.6 dN*m or greater, preferably about 3.0 dN*m or greater, preferably between about 3.6 dN*m and about 8.0 dN*m, and more preferably between about dN*m 5.0 and about dN*m 8.0.

12. The photovoltaic module of claim 1 wherein said polyethylene composition comprises one or more C₃ to C₁₂ modifiers.

13. The photovoltaic module of claim 1 wherein said layer is a backsheet layer and said backsheet layer further comprises polyisobutylene.

14. A method of making a photovoltaic cell comprising:
providing a layer comprising a polyethylene composition, wherein said polyethylene composition comprises:
a. 50.0 wt % to 99.5 wt % of polymer units derived from ethylene, and
b. 0.5 wt % to 50.0 wt % of polymer units derived from at least one C₄ to C₆ alpha-olefin comonomer,
based on the total weight of said polyethylene composition, and said polyethylene composition has a density, according to ASTM D1505 at 23° C., of 0.86 g/cm³ to 0.91 g/cm³.

15. The method of claim 14 wherein said layer further comprises at least one component selected from ethylene vinyl acetate, ethylene methyl acrylate, ethylene butyl acrylate, ethylene ethyl acrylate, ethylene acrylic acid and ethylene metacrylic acid copolymer or ionomer or terpolymer.

16. The method of claim 15 wherein the amount of said at least one component is from 5 wt % to 95 wt %, based on the total weight of said layer.

17. The method of claim 14 wherein said layer comprises less than 0.001 mole % of any of ethylene vinyl acetate, ethylene methyl acrylate, ethylene butyl acrylate, ethylene ethyl acrylate, ethylene acrylic acid and ethylene metacrylic acid copolymer or ionomer or terpolymer.

18. The method of claim 14 wherein said polyethylene composition has a melt index, according to ASTM D1238 at 190° C./2.16 kg, of about 0.1 g/10 min to about 200.0 g/10 min.

19. The method of claim 14 wherein said polyethylene composition has a melt index, according to ASTM D1238 at 190° C./2.16 kg, of about 0.1 g/10 min to about 40.0 g/10 min.

20. The method of claim 14 wherein said polyethylene composition has a melt index, according to ASTM D1238 at 190° C./2.16 kg, of about 0.9 g/10 min to about 4.5 g/10 min.

21. The method of claim 14 wherein said polyethylene composition comprises:
a. at least 50.0 wt % of polymer units derived from ethylene, and
b. 1.0 wt % to 35.0 wt % of polymer units derived from at least one C₄ to C₆ alpha-olefin,
based on the total weight of said polyethylene composition, and said polyethylene composition has a composition distribution breadth index above 90%, a density according to ASTM D1505 at 23° C. of 0.873 g/cm³ to 0.888 g/cm³, and a melt index according to ASTM D1238 at 190° C./2.16 kg of 0.5 g/10 min to 5 g/10 min.

22. The method of claim 14 wherein said polyethylene composition has a density, according to ASTM D1505 at 23° C., of about 0.873 g/cm³ to about 0.888 g/cm³.

23. The method of claim 14 wherein said polyethylene composition has a crosslink index (MH-ML) of about 1.6 dN*m or greater, preferably about 3.0 dN*m or greater, preferably between about 3.6 dN*m and about 8.0 dN*m, and more preferably between about 5.0 dN*m and about 8.0 dN*m.

24. The method of claim 14 wherein said polyethylene composition comprises one or more C₃ to C₁₂ modifiers.

25. The method of claim 14 wherein said layer is a backsheet layer and said backsheet layer further comprises polyisobutylene.
